(19) United States
(12) Patent Application Publication
(10) Pub. No.: US 2025/0393186 A1
(43) Pub. Date: Dec. 25, 2025

(54) SEMICONDUCTOR DEVICE AND METHOD FOR FORMING THE SAME

(71) Applicant: NANYA TECHNOLOGY CORPORATION, New Taipei City (TW)

(72) Inventor: Hsu CHIANG, New Taipei City (TW)

(21) Appl. No.: 18/747,482

(22) Filed: Jun. 19, 2024

(51) Int. Cl. H10B 12/00

(52) U.S. Cl. CPC H10B 12/053; H10B 12/34

(57) ABSTRACT

A method includes forming a dielectric layer over a substrate; forming an opening in the dielectric layer and the substrate; forming a gate structure in the opening; removing the dielectric layer to expose sidewalls of the gate structure; forming first gate spacers along the sidewalls of the gate structure; performing a first implantation process to form lightly-doped drain (LDD) regions in the substrate; performing a second implantation process to form halo regions in the substrate; and forming source/drain regions in the substrate.

### BACKGROUND

### Field of the Invention

The present invention relates generally to method of fabricating a semiconductor device and, more particularly, to a method for fabricating a recessed-gate metal-oxide-semiconductor (MOS) transistor device.

### Description of Related Art

With the continuing shrinkage of device feature size, the so-called short channel effect (SCE) due to shrunk gate channel length has been found that it can hinder the integrity of integrated circuit chips. Many efforts have been made for solving this problem, for example, by reducing the thickness of the gate oxide dielectric or by increasing the doping concentration of source/drain. However, these approaches adversely affect the device reliability and speed of data transfer on the other hand, and are thus impractical.

A newly developed recessed-gate MOS transistor becomes most promising. In the field of Dynamic Random Access Memory (DRAM), the recessed-gate technology may be used to improve the integrity of the memory chip. Typically, the recess-gate MOS transistor has a gate insulation layer formed on sidewalls and bottom surface of a recess etched into a substrate, a conductive filling the recess, contrary to a planar gate type transistor having a gate electrode formed on a planar surface of a substrate.

### SUMMARY

In some embodiments of the present disclosure, a method for forming a semiconductor device includes forming a dielectric layer over a substrate; forming an opening in the dielectric layer and the substrate; forming a gate structure in the opening; removing the dielectric layer to expose sidewalls of the gate structure; forming first gate spacers along the sidewalls of the gate structure; performing a first implantation process to form lightly-doped drain (LDD) regions in the substrate; performing a second implantation process to form halo regions in the substrate; and forming source/drain regions in the substrate.

In some embodiments, forming the opening in the dielectric layer includes performing an anisotropic etching to the dielectric layer, such that the opening has straight opposite sidewalls, and the gate structure is formed along the straight opposite sidewalls of the opening.

In some embodiments, an incident direction of the first implantation process is substantially vertical to a top surface of the substrate, and an incident direction of the second implantation process is substantially vertical to the top surface of the substrate.

In some embodiments, the halo regions are formed overlapping the LDD regions respectively, and the halo regions include an opposite conductivity type than the LDD regions.

In some embodiments, the method further includes etching the substrate through the opening of the dielectric layer to form a gate trench extending into the substrate, in which forming the gate structure further includes depositing a conductive gate material in the gate trench, and the conductive gate material is doped polysilicon.

In some embodiments, the method further includes etching back the conductive gate material such that a top surface of the conductive gate material is lower than a top surface of the dielectric layer; and forming a metal layer over the conductive gate material.

In some embodiments, the source/drain regions are formed in contact with the LDD regions and the halo regions.

In some embodiments, the method further includes forming second gate spacers along the first gate spacers, respectively; and forming an inter-layer dielectric layer over the substrate and covering the source/drain regions.

In some embodiments, the source/drain regions include a same conductivity type as the LDD regions, and have a higher dopant concentration than the LDD regions.

In some embodiments, the gate structure includes a gate dielectric layer, a conductive gate material over the gate dielectric layer, a metal layer over the conductive gate material, and a dielectric cap layer over the metal layer.

In some embodiments of the present disclosure, a semiconductor device includes a substrate. A gate structure is over the substrate, in which the gate structure has a portion extending into the substrate. A first gate spacer is along a sidewall of the gate structure, in which the first gate spacers have a substantially vertical profile. A lightly doped drain (LDD) region is in the substrate and adjacent to the gate structure. A halo region is in the substrate and adjacent to the gate structure, in which the halo region has an opposite conductivity type than the LDD region.

In some embodiments, the gate structure includes a poly silicon layer in the substrate, a metal layer over the poly silicon layer, a gate dielectric layer between the poly silicon layer and the substrate.

In some embodiments, an edge of the halo region in contact with the gate dielectric layer is vertically aligned with an edge of the LDD region in contact with the gate dielectric layer.

In some embodiments, the edge of the halo region is vertically aligned with a sidewall of the first gate spacer.

In some embodiments, the semiconductor device further includes a second gate spacer along the first gate spacer and overlapping the LDD region and the halo region.

In some embodiments, the second gate spacer has a substantially vertical profile.

In some embodiments, the semiconductor device further includes a source/drain region in the substrate and in contact with the LDD region and the halo region.

In some embodiments, an edge of the source/drain region is vertically aligned with a sidewall of the second gate spacer.

In some embodiments, a bottom end of the LDD region is lower than a bottom end of the halo region.

In some embodiments, the gate structure includes a poly silicon layer in the substrate, a first metal layer over the poly silicon layer, a second metal layer over the first metal layer, a third metal layer over the second metal layer, a dielectric cap over the third metal layer, and a gate dielectric layer between the poly silicon layer and the substrate.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1 to 15 illustrate a method in various stages of forming a semiconductor device in accordance with some embodiments of the present disclosure.

FIG. 16 illustrates a semiconductor device in accordance with some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

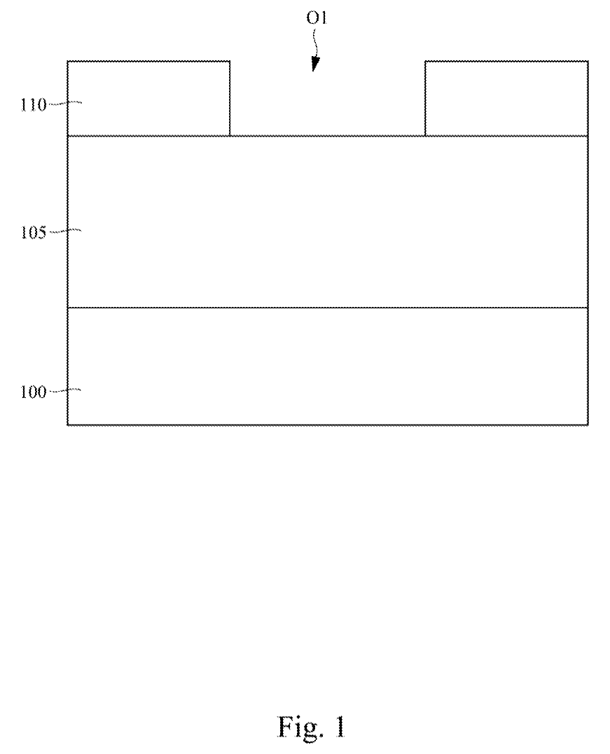

FIGS. 1 to 15 illustrate a method in various stages of forming a semiconductor device in accordance with some embodiments of the present disclosure.

Reference is made to FIG. 1. Shown there is a semiconductor substrate 100. In some embodiments, the semiconductor substrate 100 may be a silicon substrate, silicon epitaxial substrate, silicon-on-insulator (SOI) substrate, or other suitable materials of semiconductor substrate.

A dielectric layer 105 is formed over the semiconductor substrate 100. In some embodiments, the dielectric layer 105 is in contact with top surface of the semiconductor substrate 100. According to some embodiments, the dielectric layer 105 may be made of oxide, such as silicon oxide (SiO₂). For example, the dielectric layer 105 may be TEOS-based CVD oxide that is deposited by using tetra-ethyl-ortho-silicate as precursor, but the present disclosure is not limited thereto.

A photoresist layer 110 is formed over the dielectric layer 105. The photoresist layer 110 includes an opening O1 exposing a portion of the underlying dielectric layer 105. In some embodiments, a lithographic process is carried out to form the opening O1 in the photoresist layer 110.

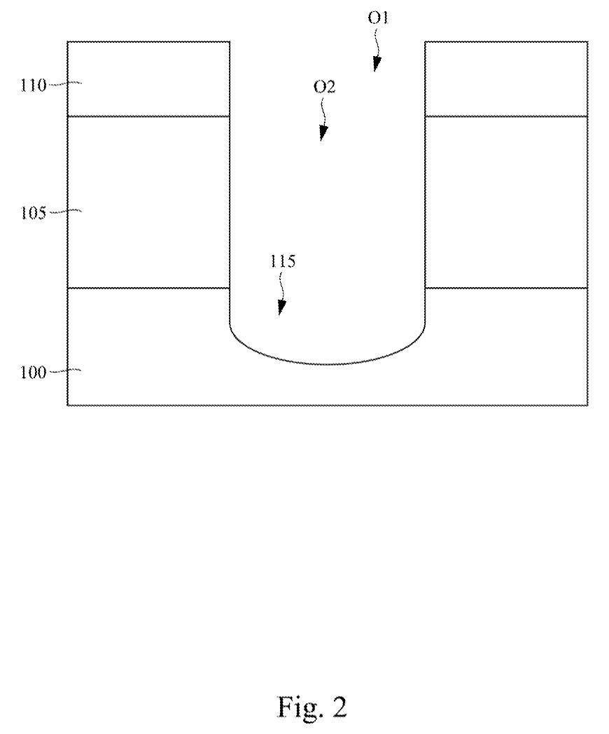

Reference is made to FIG. 2. An etching process is then performed to etch the dielectric layer 105 through the opening O1 using the photoresist layer 110 as an etching mask, thereby forming an opening O2 in the dielectric layer 105 that exposes a portion of the semiconductor substrate 100. In some embodiments, the opening O2 has straight opposite sidewalls. The semiconductor substrate 100 is then etched through the opening O2 in the dielectric layer 105 to form a gate trench 115 in the semiconductor substrate 100. In some embodiments, the etching process may be an anisotropic dry etching process.

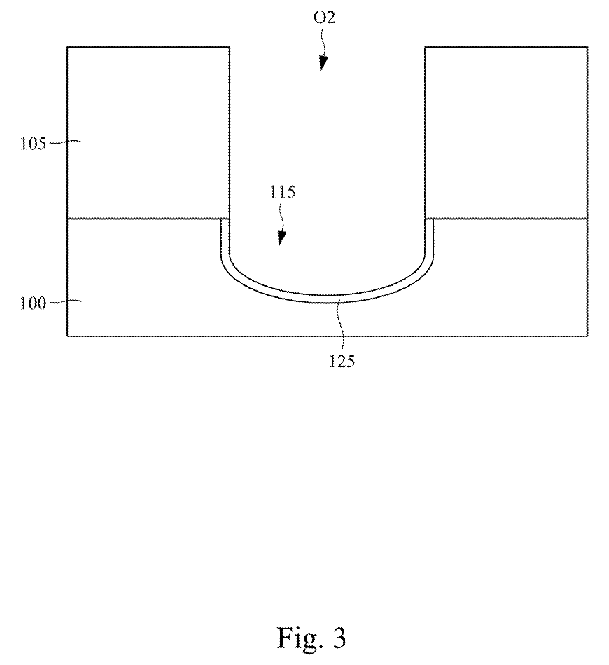

Reference is made to FIG. 3. After the gate trench 115 is formed, the photoresist layer 110 is removed. In some embodiments, the photoresist layer 110 may be removed using a stripping process or an ashing process.

Afterwards, a gate dielectric layer 125 is formed on the exposed surface of the semiconductor substrate 100 in the gate trench 115 through the opening O2 in the dielectric layer 105. In some embodiments, the gate dielectric layer 125 may be oxide, such as silicon oxide, or other suitable materials. In some embodiments, the gate dielectric layer 125 may be formed using a thermal oxidation process or a In-Situ Steam Growth (ISSG) technology. In some embodiments, the gate dielectric layer 125 is deposited in a selective manner. For example, the gate dielectric layer 125 is formed only along the exposed surface of the semiconductor substrate 100, and may not be formed on the exposed surface of the dielectric layer 105. That is, the exposed surface of the dielectric layer 105 may be free of coverage by the material of the gate dielectric layer 125 during and after forming the gate dielectric layer 125.

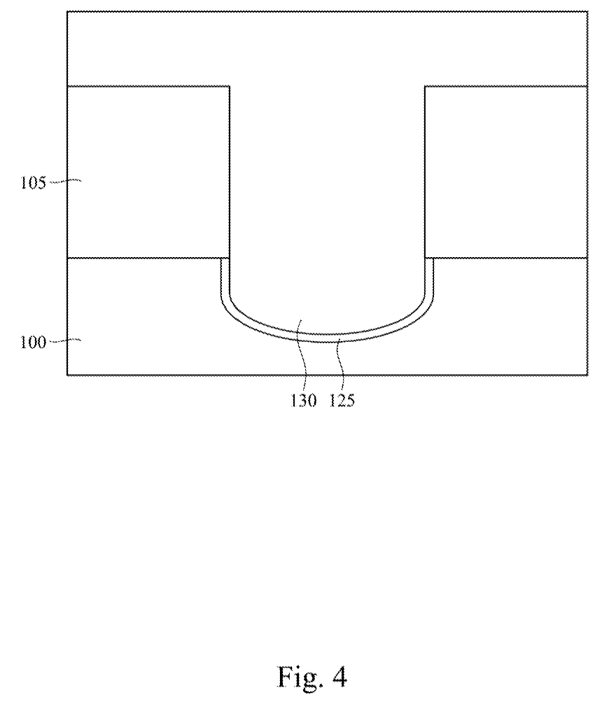

Reference is made to FIG. 4. A conductive gate material 130 is deposited in the gate trench 115 in the semiconductor substrate 100 and overfilling the opening O2 in the dielectric layer 105. In some embodiments, the conductive gate material 130 is in contact with sidewall and top surface of the dielectric layer 105. In some embodiments, the conductive gate material 130 may be doped polysilicon.

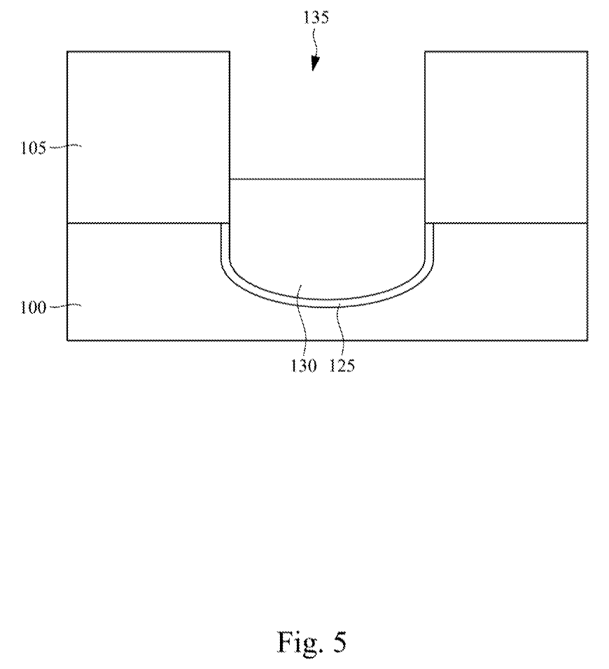

Reference is made to FIG. 5. The conductive gate material 130 is then etched back to a pre-determined depth such that the top surface of the conductive gate material 130 is lower than the top surface of the dielectric layer 105, thereby forming a recess 135 in the dielectric layer 105 and over the conductive gate material 130. In some embodiments, the etching back process may include a dry etch.

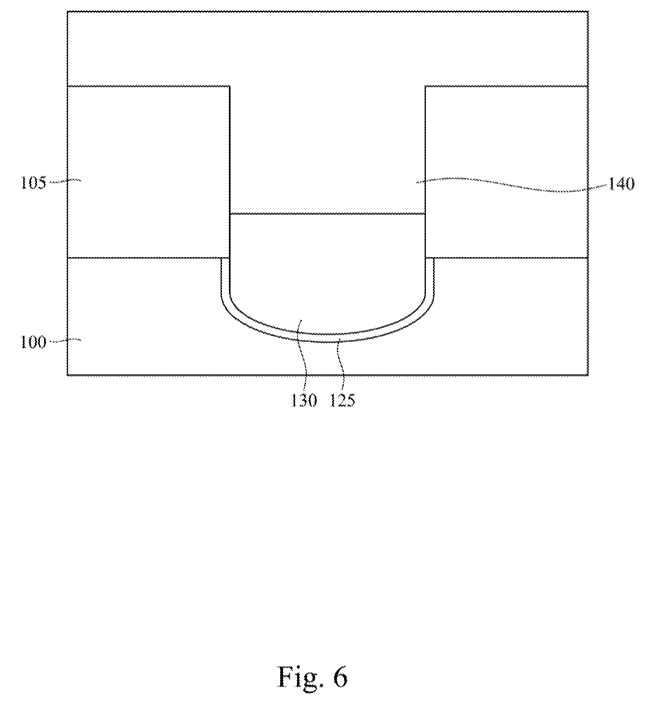

Reference is made to FIG. 6. A metal layer 140 is deposited over the conductive gate material 130 and overfilling the recess 135 in the dielectric layer 105. In some embodiments, the metal layer 140 may include tungsten (W), or other suitable material. In some embodiments, the metal layer 140 is in contact with top surface of the conductive gate material 130 and the dielectric layer 105.

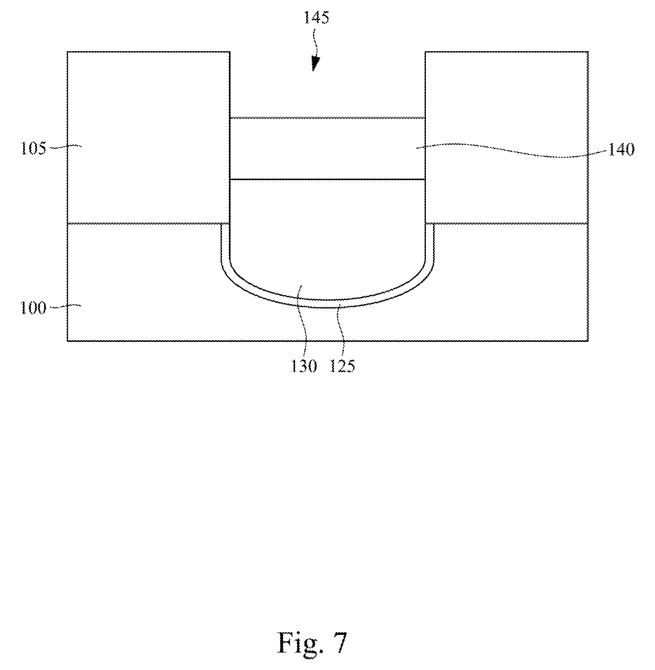

Reference is made to FIG. 7. After the deposition of the metal layer 140, an etching process is performed to etch back the metal layer 140 to a pre-determined depth such that the top surface of the metal layer 140 is lower than the top surface of the dielectric layer 105, thereby forming a recess 145 in the dielectric layer 105 and over the metal layer 140. In some embodiments, the etching process may include a dry etch.

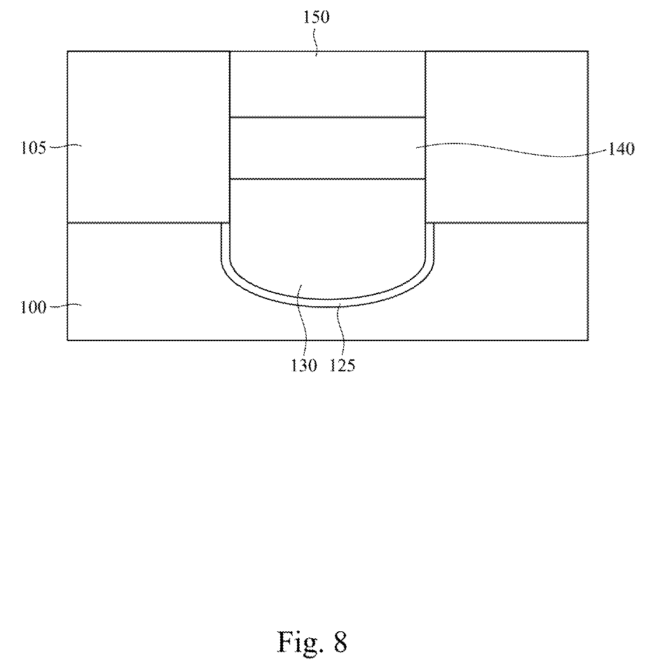

Reference is made to FIG. 8. A dielectric cap layer 150 is formed over the metal layer 140. The dielectric cap layer 150 is formed by depositing a dielectric material overfilling the recess 145 in the dielectric layer 105, followed by a planarization process such as an etching back process or Chemical Mechanical Polishing (CMP) process. As a result, the top surface of the dielectric cap layer 150 may be substantially coplanar to the topmost surface of the dielectric layer 105. In some embodiments, the dielectric cap layer 150 may include silicon nitride (SiN), or other suitable dielectric materials.

The gate dielectric layer 125, conductive gate material 130, the metal layer 140, and the dielectric cap layer 150 can be collectively referred to as a gate structure. Based on the above discussion, an opening O2 is formed in the dielectric layer 105 and the substrate 100 by using an anisotropic etching process. The anisotropic etching process may ensure that the opening O2 includes substantially straight opposite sidewalls. Accordingly, the gate structure may be formed self-aligned in the opening O2, resulting the gate structure having substantially straight opposite sidewalls.

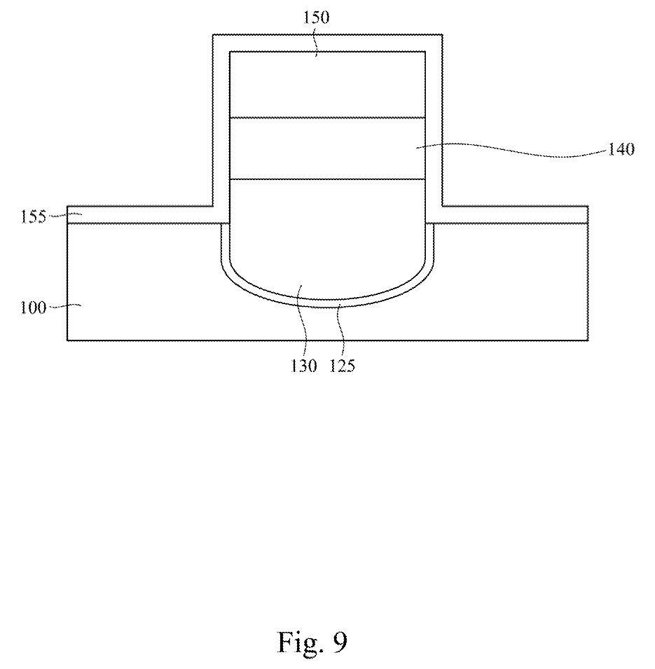

Reference is made to FIG. 9. After the formation of the dielectric cap layer 150, an etching process is performed to remove the dielectric layer 105. In some embodiments, the etching process may be dry etch, wet etch, or combinations thereof.

Next, a spacer layer 155 is conformally formed on the dielectric cap layer 150, the metal layer 140, the conductive gate material 130, and the semiconductor substrate 100. In some embodiments, the spacer layer 155 may be formed in contact with the top surface of the dielectric cap layer 150. In some embodiments, the spacer layer 155 may be formed in contact with the top surface of the semiconductor substrate 100. In some embodiments, the spacer layer 155 may be a spacer including nitride, silicon nitride, silicon oxynitride or other suitable dielectric materials. The spacer layer 155 may be formed using a conformal deposition method, such as chemical vapor deposition (CVD), atomic layer deposition (ALD), or the like.

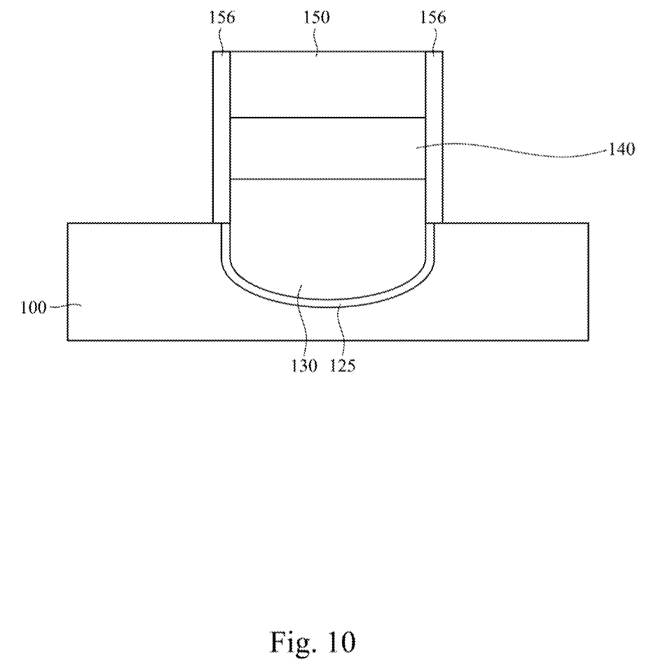

Reference is made to FIG. 10. After the deposition of the spacer layer 155, an etching process is performed to etch the spacer layer 155, so as to form gate spacers 156 on opposite sidewalls of the conductive gate material 130, the metal layer 140, and the dielectric cap layer 150. In greater detail, the etching process is performed to remove the horizontal portions of the spacer layer 155, while leaving the vertical portions of the spacer layer 155 remain after the etching process is completed. The remaining portions of the spacer layer 155 are referred to as the gate spacers 156. In some embodiments, the etching process may be an anisotropic dry etching process.

The gate spacers 156 are formed along the substantially straight opposite sidewalls of the gate structure (e.g., the gate dielectric layer 125, conductive gate material 130, the metal layer 140, and the dielectric cap layer 150), and thus each of the gate spacers 156 may include a substantially vertical profile. This will be beneficial to control the position of the following formed LDD regions and halo regions, and will be discussed in more detail later. In some embodiments, the gate spacers 156 have a substantially vertical profile.

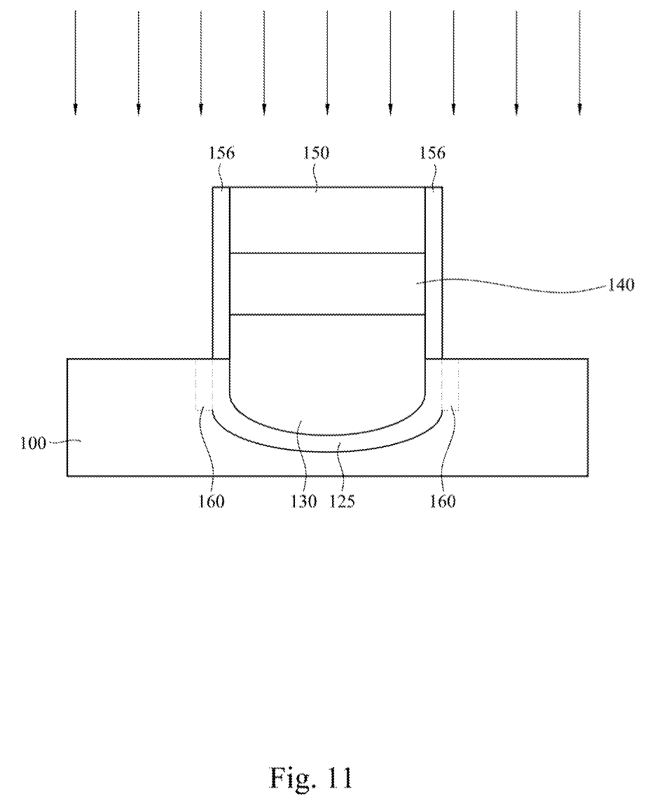

Reference is made to FIG. 11. After the gate spacers 156 are formed, a first implantation process is performed to dope the semiconductor substrate 100, such that lightly doped drain (LDD) regions 160 are formed in the semiconductor substrate 100, and on opposite sides of the conductive gate material 130. In some embodiments, an incident direction of the first implantation is substantially vertical to a top surface of the substrate. In some embodiments, for an NMOS device, the LDD regions 160 may be doped with N-type dopants (such as phosphorus (P), arsenic (As), or antimony (Sb)) and the channel region (e.g., substrate 100) may be doped with P-type dopants. In some other embodiments, for a PMOS device, the LDD regions 160 may be doped with P-type dopants (such as boron (B) or indium (In)) and the channel region (e.g., substrate 100) may be doped with N-type dopants. In some embodiments, the LDD regions 160 can reduce the amount of the carrier at the junctions, thereby reducing the hot carrier effect. In some embodiments, the dopant concentration of the LDD regions 160 is ranged from about 1x10¹² cm⁻³ to about 1x10¹⁵ cm⁻³.

As mentioned above, because the gate spacers 156 have substantially vertical profile, the first implantation process can be performed without tilted angle. That is, the incident direction of the first implantation process is substantially vertical to the top surface of the substrate 100. Thus, the position of the LDD regions 160 can be well-controlled in one dimension (e.g., vertical direction). However, if the gate structure is not formed using the aforementioned method, the gate structure may include tapered sidewall, and the following formed gate spacers 156 may include an inclined profile with respect to the top surface of the substrate 100. In such condition, an implantation process with tilted angle may be needed to drive the dopants into desired position in the substrate 100, while this may increase difficulty to control the position of the LDD regions 160.

In some embodiments, the gate structure may include the gate dielectric layer 125, the conductive gate material 130 over the gate dielectric layer 125, the metal layer 140 over the conductive gate material 130, and the dielectric cap layer 150 over the metal layer 140. In some embodiments, the gate structure is over the substrate, and has a portion extending into the substrate.

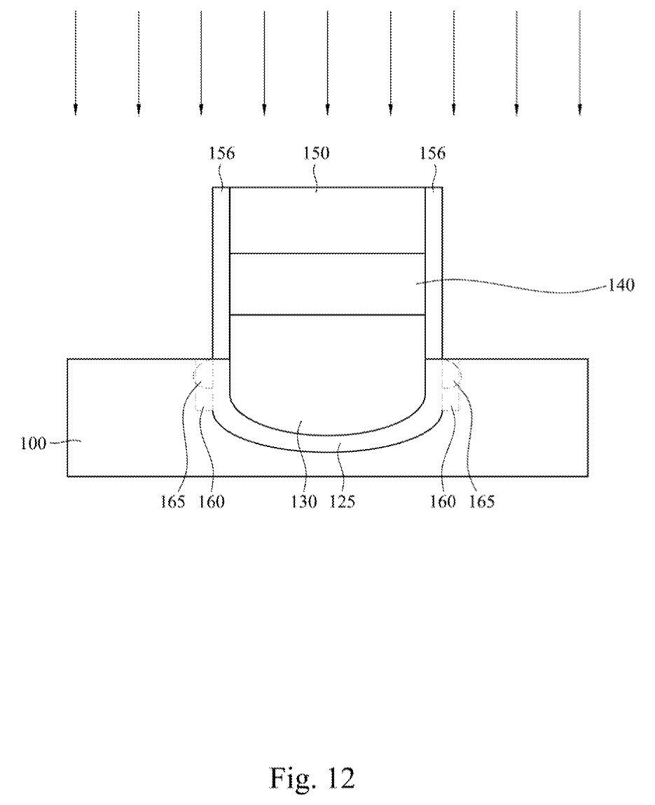

Reference is made to FIG. 12. After the LDD regions 160 are formed, a second implantation process is performed to dope the semiconductor substrate 100, such that halo regions 165 are formed in the semiconductor substrate 100, and on opposite sides of the conductive gate material 130. In some embodiments, an incident direction of the second implantation is substantially vertical to the top surface of the substrate. In some embodiments, the halo regions 165 are formed overlapping the LDD regions 160, respectively. In some embodiments, the halo regions 165 may include an opposite conductivity type than the LDD regions 160. For example, if the LDD regions 160 include n-type dopants, the halo regions 165 may be doped be p-type dopants. Similarly, if the LDD regions 160 include p-type dopants, the halo regions 165 may be doped be n-type dopant.

In some embodiments, the halo regions 165 are formed to increase the threshold voltage of the semiconductor substrate 100. The halo regions 165 can also reduce the short channel effect of the semiconductor substrate 100. In some embodiments, the dopant concentration of the halo regions 165 is ranged from about 1x10¹² cm⁻³ to about 1x10¹⁵ cm⁻³. In some embodiments, the bottommost end of the LDD regions 160 is lower than the bottommost end of the halo regions 165.

Similarly, because the gate spacers 156 have substantially vertical profile, the second implantation process can be performed without tilted angle. That is, the incident direction of second implantation process is substantially vertical to the top surface of the substrate 100. Thus, the position of the halo regions 165 can be well-controlled in one dimension (e.g., vertical direction). Accordingly, the device performance may be improved.

Based on the discussion, the halo regions 165 may vertically overlap with the respective LDD regions 160. Moreover, in some embodiments, an edge of the halo region 165 in contact with the gate dielectric layer 125 may be vertically aligned with (or coterminous with) an edge of the respective LDD region 160 in contact with the gate dielectric layer 125. In some embodiments, the edge of the halo region 165 is vertically aligned with a sidewall of the gate spacer 156.

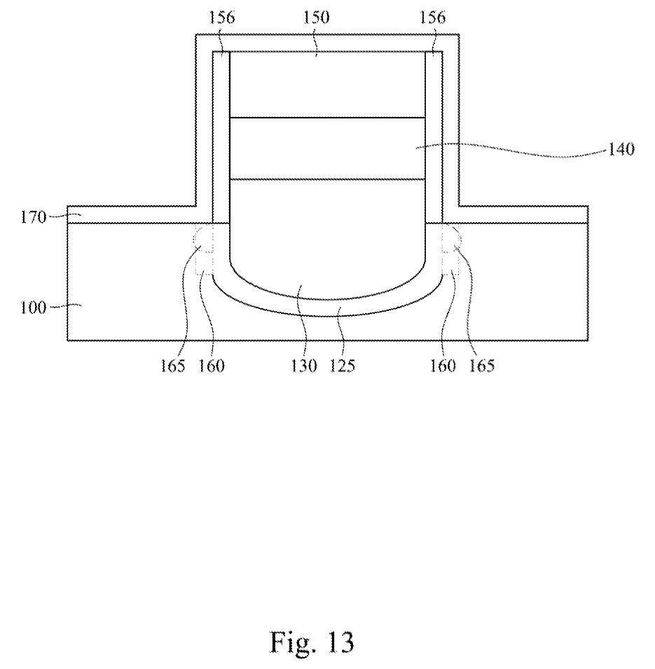

Reference is made to FIG. 13. After the halo regions 165 are formed, a spacer layer 170 is conformally formed on the gate spacers 156, the dielectric cap layer 150, and the semiconductor substrate 100. In some embodiments, the spacer layer 170 may be formed in contact with the top surface of the dielectric cap layer 150. In some embodiments, the spacer layer 170 may be formed in contact with the top surface of the semiconductor substrate 100. In some embodiments, the spacer layer 170 may be a spacer including nitride, silicon nitride, silicon oxynitride or other suitable dielectric materials. The spacer layer 170 may be formed using a conformal deposition method, such as chemical vapor deposition (CVD), atomic layer deposition (ALD), or the like.

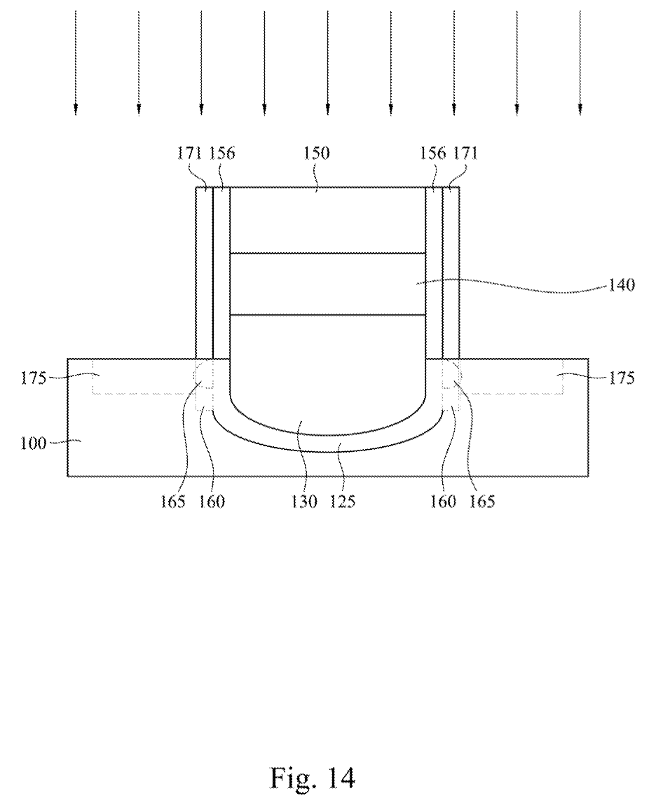

Reference is made to FIG. 14. After the deposition of the spacer layer 170, an etching process is performed to etch the spacer layer 170, so as to form gate spacers 171 adjacent to the gate spacers 156. In greater detail, the etching process is performed to remove the horizontal portions of the spacer layer 170, while leaving the vertical portions of the spacer layer 170 remain after the etching process is completed. The remaining portions of the spacer layer 170 are referred to as the gate spacers 171. In some embodiments, the etching process may be an anisotropic dry etching process. As shown in FIG. 14, the gate spacers 171 vertically overlap with the respective LDD regions 160 and the respective halo regions 165. In some embodiments, the gate spacers 171 have a substantially vertical profile.

After the gate spacers 171 are formed, a third implantation process is performed to dope the substrate 100, so as to form source/drain regions 175 in the substrate 100. In some embodiments, an edge of the source/drain region 175 is vertically aligned with the sidewalls of the gate spacers 171. In some embodiments, the source/drain regions 175 may be laterally adjacent to and in contact with the respective LDD regions 160 and the respective halo regions 165. The source/drain regions 175 may include a same conductivity type as the LDD regions 160, while having a higher dopant concentration than the LDD regions 160. In some embodiments, the bottommost end of the source/drain regions 175 is lower than the bottommost end of the halo regions 165. In some embodiments, the dopant concentration of the source/drain regions 175 is ranged from about 1x10¹² cm⁻³ to about 1x10¹⁵ cm⁻³.

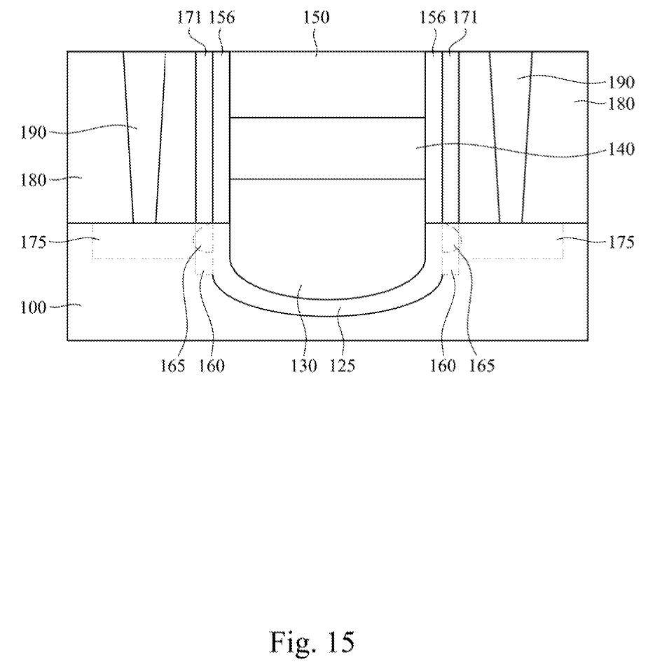

Reference is made to FIG. 15. An inter-layer dielectric (ILD) layer 180 is formed over the substrate 100 and covering the source/drain regions 175. In some embodiments, the ILD layer 180 is formed by depositing a dielectric material over the substrate 100, followed by a planarization process such as an etching back process and/or Chemical Mechanical Polishing (CMP) process. In some embodiments, the CMP process is used to planarize the ILD layer 180 such that the top surface of the ILD layer 180 is substantially level with the top of the dielectric cap layer 150.

After the ILD layer 180 is formed, source/drain contacts 190 are formed in the ILD layer 180 and electrically connected with the respective source/drain regions 175. In some embodiments, the source/drain contacts 190 may be formed by, for example, patterning the ILD layer 180 to form openings that expose the source/drain regions 175, filling the openings with conductive material, and then performing a planarization process, such as CMP, to remove excess conductive material until the ILD layer 180 is exposed.

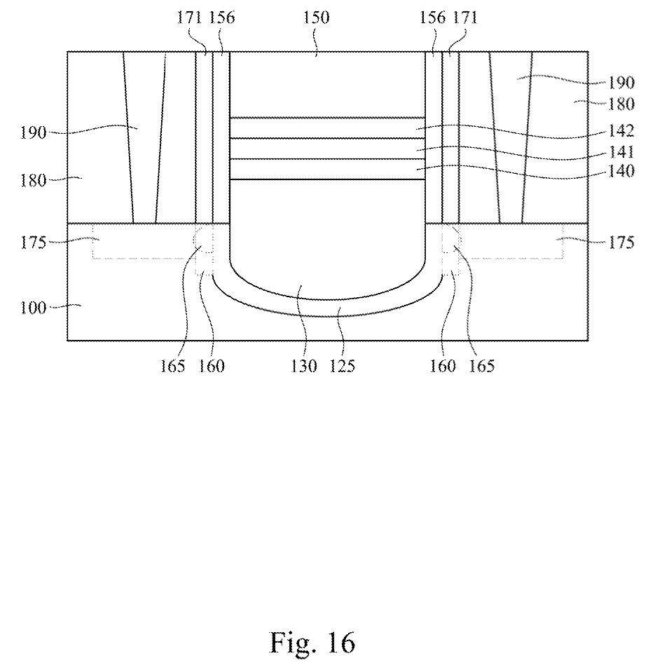

FIG. 16 illustrates a semiconductor device in accordance with some embodiments of the present disclosure. Some elements in the structure of FIG. 16 are similar to those described with respect to the structure of FIG. 15, such elements are labeled the same, and relevant details will not be repeated for brevity.

In the structure of FIG. 16, a metal layer 141 is disposed over the conductive gate material 130, a metal layer 142 is disposed over the metal layer 141, and a metal layer 143 is disposed over the metal layer 143. The metal layers 141, 142, and 143 may be made of different materials. For example, the metal layer 141 may be made of titanium (Ti), the metal layer 142 may be made of tungsten nitride (WN), and the metal layer 142 may be made of tungsten (W). In some embodiments, the metal layers 141, 142, and 143 are in contact with the gate spacers 156. The metal layers 141, 142, and 143 may be formed by, for example, sequentially forming the metal layers 141, 142, and 143 in the recess 135 of the dielectric layer 105 (see FIG. 4) and over the conductive gate material 130. Once the metal layers 141, 142, and 143 are formed, the dielectric cap layer 150 is then formed over the metal layer 143.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a semiconductor device, comprising:
forming a dielectric layer over a substrate;
forming an opening in the dielectric layer and the substrate;
forming a gate structure in the opening;
removing the dielectric layer to expose sidewalls of the gate structure;
forming first gate spacers along the sidewalls of the gate structure;
performing a first implantation process to form lightly-doped drain (LDD) regions in the substrate;
performing a second implantation process to form halo regions in the substrate; and
forming source/drain regions in the substrate.

2. The method of claim 1, wherein forming the opening in the dielectric layer comprises performing an anisotropic etching to the dielectric layer, such that the opening has straight opposite sidewalls, and the gate structure is formed along the straight opposite sidewalls of the opening.

3. The method of claim 1, wherein,
an incident direction of the first implantation process is substantially vertical to a top surface of the substrate, and
an incident direction of the second implantation process is substantially vertical to the top surface of the substrate.

4. The method of claim 1, wherein,
the halo regions are formed overlapping the LDD regions respectively, and
the halo regions include an opposite conductivity type than the LDD regions.

5. The method of claim 1, further comprising etching the substrate through the opening of the dielectric layer to form a gate trench extending into the substrate, wherein forming the gate structure further comprises depositing a conductive gate material in the gate trench, and the conductive gate material is doped polysilicon.

6. The method of claim 5, further comprising:
etching back the conductive gate material such that a top surface of the conductive gate material is lower than a top surface of the dielectric layer; and
forming a metal layer over the conductive gate material.

7. The method of claim 1, wherein the source/drain regions are formed in contact with the LDD regions and the halo regions.

8. The method of claim 7, further comprising:
forming second gate spacers along the first gate spacers, respectively; and
forming an inter-layer dielectric layer over the substrate and covering the source/drain regions.

9. The method of claim 1, wherein the source/drain regions include a same conductivity type as the LDD regions, and have a higher dopant concentration than the LDD regions.

10. The method of claim 1, wherein the gate structure includes a gate dielectric layer, a conductive gate material over the gate dielectric layer, a metal layer over the conductive gate material, and a dielectric cap layer over the metal layer.

11. A semiconductor device, comprising:
a substrate;
a gate structure over the substrate, wherein the gate structure has a portion extending into the substrate;
a first gate spacer along a sidewall of the gate structure, wherein the first gate spacers have a substantially vertical profile;
a lightly doped drain (LDD) region in the substrate and adjacent to the gate structure; and
a halo region in the substrate and adjacent to the gate structure, wherein the halo region has an opposite conductivity type than the LDD region.

12. The semiconductor device of claim 11, wherein the gate structure comprises:
a poly silicon layer in the substrate;
a metal layer over the poly silicon layer; and
a gate dielectric layer between the poly silicon layer and the substrate.

13. The semiconductor device of claim 12, wherein an edge of the halo region in contact with the gate dielectric layer is vertically aligned with an edge of the LDD region in contact with the gate dielectric layer.

14. The semiconductor device of claim 13, wherein the edge of the halo region is vertically aligned with a sidewall of the first gate spacer.

15. The semiconductor device of claim 11, further comprising a second gate spacer along the first gate spacer and overlapping the LDD region and the halo region.

16. The semiconductor device of claim 15, wherein the second gate spacer has a substantially vertical profile.

17. The semiconductor device of claim 15, further comprising a source/drain region in the substrate and in contact with the LDD region and the halo region.

18. The semiconductor device of claim 17, wherein an edge of the source/drain region is vertically aligned with a sidewall of the second gate spacer.

19. The semiconductor device of claim 11, wherein a bottom end of the LDD region is lower than a bottom end of the halo region.

20. The semiconductor device of claim 11, wherein the gate structure comprises:
a poly silicon layer in the substrate;
a first metal layer over the poly silicon layer;
a second metal layer over the first metal layer;
a third metal layer over the second metal layer;
a dielectric cap over the third metal layer; and
a gate dielectric layer between the poly silicon layer and the substrate.
